(19) United States
(12) Patent Application Publication
(10) Pub. No.: US 2024/0329539 A1
(43) Pub. Date: Oct. 3, 2024

(54) MULTI-STEP POST-EXPOSURE TREATMENT TO IMPROVE DRY DEVELOPMENT PERFORMANCE OF METAL-CONTAINING RESIST

(71) Applicant: Lam Research Corporation, Fremont, CA (US)

(72) Inventors: Samantha SiamHwa TAN, Newark, CA (US); Da LI, Newark, CA (US); Jengyi YU, San Ramon, CA (US); Ji Yeon KIM, Fremont, CA (US); Yang PAN, Los Altos, CA (US)

(21) Appl. No.: 18/579,777

(22) PCT Filed: Jul. 15, 2022
(86) PCT No.: PCT/US2022/037393

§ 371 Date: Jan. 16, 2024

Related U.S. Application Data
(60) Provisional application No. 63/203,507, filed on Jul. 26, 2021.

(51) Int. Cl. G03F 7/38; G03F 7/004; G03F 7/36

(52) U.S. Cl. CPC G03F 7/38; G03F 7/0043; G03F 7/36

(57) ABSTRACT

Various embodiments described herein relate to methods, apparatus, and systems for treating metal-containing photoresist to modify material properties of the photoresist. The metal-containing photoresist may be treated in a post-exposure bake process involving at least two thermal operations. At least one of the post-exposure bake operations includes exposing the metal-containing photoresist to a moderately elevated temperature in an oxygen-rich atmosphere. This is followed by a post-exposure bake operation that includes exposing the metal-containing photoresist to a highly elevated temperature in an inert gas atmosphere. The multi-step post-exposure bake operations improves etch electivity in a subsequent dry development process.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate treatment of photoresist material and, more particularly, to treatment of metal-containing photoresist material after exposure in semiconductor fabrication.

### BACKGROUND

The fabrication of semiconductor devices, such as integrated circuits, is a multi-step process involving photolithography. In general, the process includes the deposition of material on a wafer, and patterning the material through lithographic techniques to form structural features (e.g., transistors and circuitry) of the semiconductor device. The steps of a typical photolithography process known in the art include: preparing the substrate; applying a photoresist, such as by spin coating; exposing the photoresist to light in a desired pattern, causing the exposed areas of the photoresist to become more or less soluble in a developer solution; developing by applying a developer solution to remove either the exposed or the unexposed areas of the photoresist; and subsequent processing to create features on the areas of the substrate from which the photoresist has been removed, such as by etching or material deposition.

The evolution of semiconductor design has created the need, and has been driven by the ability, to create ever smaller features on semiconductor substrate materials. This progression of technology has been characterized in “Moore's Law” as a doubling of the density of transistors in dense integrated circuits every two years. Indeed, chip design and manufacturing has progressed such that modern microprocessors may contain billions of transistors and other circuit features on a single chip. Individual features on such chips may be on the order of 22 nanometers (nm) or smaller, in some cases less than 10 nm.

One challenge in manufacturing devices having such small features is the ability to reliably and reproducibly create photolithographic masks having sufficient resolution. Current photolithography processes typically use 193 nm ultraviolet (UV) light to expose a photoresist. The fact that the light has a wavelength significantly greater than the desired size of the features to be produced on the semiconductor substrate creates inherent issues. Achieving feature sizes smaller than the wavelength of the light requires use of complex resolution enhancement techniques, such as multipatterning. Thus, there is significant interest and research effort in developing photolithographic techniques using shorter wavelength light, such as extreme ultraviolet radiation (EUV), having a wavelength of from 10 nm to 15 nm, e.g., 13.5 nm.

EUV photolithographic processes can present challenges, however, including low power output and loss of light during patterning. Traditional organic chemically amplified resists (CAR) similar to those used in 193 nm UV lithography have potential drawbacks when used in EUV lithography, particularly as they have low absorption coefficients in EUV region and the diffusion of photo-activated chemical species can result in blur or line edge roughness. Furthermore, in order to provide the etch resistance required to pattern underlying device layers, small features patterned in conventional CAR materials can result in high aspect ratios at risk of pattern collapse. Accordingly, there remains a need for improved EUV photoresist materials, having such properties as decreased thickness, greater absorbance, and greater etch resistance.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of treating metal-containing extreme ultraviolet (EUV) photoresist. The method includes providing a substrate in a process chamber, where the substrate is a semiconductor substrate comprising a substrate layer and a metal-containing EUV photoresist positioned over the substrate layer, exposing the metal-containing EUV photoresist to a first elevated temperature in an oxygen-containing environment in the process chamber, and exposing the metal-containing EUV photoresist to a second elevated temperature in an inert gas environment, where the second elevated temperature is greater than the first elevated temperature.

In some implementations, the metal-containing EUV photoresist includes EUV-exposed portions and EUV-unexposed portions, where exposure to the first elevated temperature in the oxygen-containing environment and exposure to the second elevated temperature in the inert gas environment increase etch selectivity between the EUV-exposed portions and the EUV-unexposed portions in a subsequent dry development process. In some implementations, exposure to the first elevated temperature in the oxygen-containing environment and exposure to the second elevated temperature in the inert gas environment reduce line edge roughness (LER) and reduce dose to size (DtS) in the subsequent dry development process. In some implementations, the method further includes exposing the metal-containing EUV photoresist to EUV radiation prior to providing the substrate in the process chamber in order to form the EUV-exposed regions and the EUV-unexposed regions. In some implementations, a first queue time between exposure to EUV radiation and exposure to the first elevated temperature is less than about 20 minutes, and a second queue time between exposure to the first elevated temperature and exposure to the second elevated temperature is less than about 1 hour. In some implementations, the first elevated temperature is between about 150° C. and about 220° C. and the second elevated temperature is between about 220° C. and about 250° C. In some implementations, the oxygen-containing environment includes an oxygen-containing species, where a partial pressure of the oxygen-containing species is at least about 100 Torr in the oxygen-containing environment. In some implementations, the oxygen-containing environment includes oxygen (O₂), ozone (O₃), water (H₂O), hydrogen peroxide (H₂O₂), carbon monoxide (CO), carbon dioxide (CO₂), or combinations thereof. In some implementations, the inert gas environment includes nitrogen (N₂), helium (He), neon (Ne), argon (Ar), xenon (Xe), or combinations thereof. In some implementations, each of the oxygen-containing environment and the inert gas environment is free or substantially free of moisture. In some implementations, the metal-containing EUV photoresist is a metal oxide-containing EUV photoresist. In some implementations, the oxygen-containing environment includes oxygen radicals and ions generated from a remote plasma source for exposing the metal-containing EUV photoresist to the oxygen radicals and ions. In some implementations, exposing the metal-containing EUV photoresist to the second elevated temperature in the inert gas environment occurs in the same process chamber as exposing the metal-containing EUV resist to the first elevated temperature in the oxygen-containing environment. In some implementations, the method further includes repeating steps of exposing the metal-containing EUV photoresist to the oxygen-containing environment and exposing the metal-containing EUV photoresist to the inert gas environment for one or more times. In some implementations, the method further includes dry developing the metal-containing EUV photoresist to selectively remove portions of the metal-containing EUV photoresist, wherein exposure to the first elevated temperature in the oxygen-containing environment and exposure to the second elevated temperature in the inert gas environment are post-exposure bake (PEB) operations performed prior to dry development.

Also provided herein is an apparatus for treating metal-containing EUV photoresist. The apparatus includes a process chamber comprising a substrate support, where the substrate support is configured to support a semiconductor substrate comprising a substrate layer and a metal-containing EUV photoresist positioned over the substrate layer, a process gas source connected with the process chamber and associated gas-flow control hardware, a substrate thermal control hardware, and a controller. The controller is configured with instructions for performing the following operations: expose the metal-containing EUV photoresist to a first elevated temperature in an oxygen-containing environment in the process chamber, and expose the metal-containing EUV photoresist to a second elevated temperature in an inert gas environment, wherein the second elevated temperature is greater than the first elevated temperature.

In some implementations, the first elevated temperature is between about 150° C. and about 220° C. and the second elevated temperature is between about 220° C. and about 250° C. In some implementations, each of the oxygen-containing environment and the inert gas environment is free or substantially free of moisture. In some implementations, a partial pressure of an oxygen-containing species is at least about 100 Torr in the oxygen-containing environment. In some implementations, the oxygen-containing environment includes an oxygen-containing species, wherein a concentration of the oxygen-containing species is at least 20 volume % in the oxygen-containing environment, wherein the oxygen-containing species oxygen (O₂), ozone (O₃), water (H₂O), hydrogen peroxide (H₂O₂), carbon monoxide (CO), carbon dioxide (CO₂), or combinations thereof.

### BRIEF DESCRIPTION OF THE DRAWINGS

FIG. 1 provides a flow chart for a method of treating a substrate according to various embodiments.

FIG. 2 illustrates a substrate over the course of several processing steps where a post-application treatment is used, according to certain embodiments.

FIG. 3 illustrates a substrate over the course of several processing steps where a post-exposure treatment is used, according to various embodiments.

FIG. 4 provides a flow chart for a method of treating a substrate in a multi-step post-exposure bake treatment according to various embodiments.

FIG. 5A illustrates a processing chamber in which certain thermally-based steps may take place.

FIG. 5B illustrates a processing chamber in which various steps may take place, including thermally-based steps as well as plasma-based steps.

FIG. 6 depicts a cluster tool having a number of different modules configured to perform different operations, in accordance with certain embodiments herein.

FIGS. 7A-7D show scanning electron microscopy (SEM) images illustrating improved material contrast and selectivity between unexposed and exposed portions of a photoresist layer that can be achieved by controlling temperature during a post-exposure bake process.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

### Treatment of Metal-Containing Resist

Patterning of thin films in semiconductor processing is often an important step in the fabrication of semiconductors. Patterning involves lithography. In conventional photolithography, such as 193 nm photolithography, patterns are printed onto a photosensitive photoresist film by exposing the photoresist to photons in selective areas defined by a photomask, thereby causing a chemical reaction in the exposed photoresist and creating a chemical contrast that can be leveraged in the development step to remove certain portions of the photoresist to form the pattern. The patterned and developed photoresist film then can be used as an etch mask to transfer the pattern into underlying films that are composed of metal, oxide, etc.

Advanced technology nodes (as defined by the International Technology Roadmap for Semiconductors) include nodes 22 nm, 16 nm, and beyond. In the 16 nm node, for example, the width of a via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

EUV lithography makes use of EUV resists that are patterned to form masks for use in etching underlying layers. EUV resists may be polymer-based chemically amplified resists (CARs) produced by liquid-based spin-on techniques. An alternative to CARs is directly photopatternable metal oxide-containing films, such as those available from Inpria Corp. (Corvallis, OR) and described, for example, in US Patent Publications US 2017/0102612, US 2016/021660, and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in International Patent Application No. PCT/US2019/31618, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

These directly photopatternable EUV resists may be composed of or contain high-EUV-absorbance metals and their organometallic oxides/hydroxides and other derivatives. Upon EUV exposure, EUV photons as well as secondary electrons generated can induce chemical reactions, such as beta-H elimination reaction in SnOx-based resist (and other metal oxide-based resists), and provide chemical functionality to facilitate cross-linking and other changes in the resist film. These chemical changes can then be leveraged in the development step to selectively remove the exposed or unexposed area of the resist film and to create an etch mask for pattern transfer.

The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, the disclosure of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

It should also be understood that the while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate, having exposed hydroxyl groups, is contacted with a hydrocarbyl-substituted tin capping agent to form a hydrocarbyl-terminated SnOx film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers. To date, these resists have been developed using a wet (solvent) approach, which requires the wafer to move to a track, where it is exposed to developing solvent, dried and baked. Wet development does not only limit productivity but can also lead to line collapse due to surface tension effects during the evaporation of solvent between fine features.

Dry development techniques have been proposed to overcome these issues by eliminating substrate delamination and interface failures. Dry development has its own challenges, including etch selectivity between unexposed and EUV exposed resist material, which can lead to a higher dose to size requirement for effective resist exposure when compared to wet development. Suboptimal selectivity can also cause photoresist corner rounding due to longer exposures under etching gas, which may increase line critical dimension (CD) variation in the following transfer etch step.

According to various aspects of this disclosure, one or more post treatments to metal and/or metal oxide-based photoresists after deposition (e.g., post-application bake (PAB)) and/or exposure (e.g., post-exposure bake (PEB)) are capable of increasing material property differences between exposed and unexposed photoresist (PR) and therefore decreasing dose to size (DtS), improving PR profile, and improving line edge roughness and line width roughness (LER/LWR) after subsequent dry development. Such processing can involve a thermal process with the control of one or more of temperature, gas ambient, and moisture, resulting in improved dry development performance in processing to follow. In some instances, a remote plasma might be used.

In the case of post-application processing (e.g., PAB), a thermal process with control of one or more of temperature, gas ambient (e.g., using one or more of the gases described herein), pressure, and moisture can be used after deposition and before exposure to change the composition of unexposed metal and/or metal oxide-containing photoresist. The change can increase the EUV sensitivity of the material and thus lower dose to size and line edge roughness can be achieved after exposure and dry development.

In the case of post-exposure processing (e.g., PEB), a thermal process with the control of one or more of temperature, gas atmosphere (e.g., using one or more of the gases described herein), pressure, and moisture can be used to change the composition of both unexposed and exposed photoresist. In some cases, the treatment may preferentially alter the composition and/or material properties of the exposed photoresist compared to the unexposed photoresist, such that the change in composition and/or material property is greater in the exposed photoresist than in the unexposed photoresist. In some other cases, the treatment may preferentially alter the composition/material properties of the unexposed photoresist compared to the exposed photoresist, such that the change in composition and/or material property is greater in the unexposed photoresist than in the exposed photoresist. These preferential interactions may arise due to chemical changes that occur during EUV exposure, for example the loss of alkyl groups within the photoresist. The changes that occur during the treatment can increase the difference in composition/material properties between the unexposed and exposed photoresist, thereby enhancing the difference in etch rate between the unexposed and exposed photoresist. A higher etch selectivity (e.g., during dry development of the pattern in the photoresist) can thereby be achieved. Due to the improved selectivity, a squarer photoresist profile can be obtained with improved surface roughness, and/or less photoresist residual/scum.

In either case, in alternative implementations, the thermal process could be replaced by or supplemented with a remote plasma process. The remote plasma process may act to increase reactive species, thereby lowering the energy barrier for a desired reaction and increasing productivity. Remote plasma can generate more reactive radicals and therefore lower the reaction temperature/time for the treatment (e.g., as compared to treatments that rely solely on thermal energy), leading to increased productivity.

Accordingly, one or multiple processes may be applied to modify photoresist itself to increase dry development selectivity. This thermal and/or radical modification can increase the contrast between unexposed and exposed material and thus increase the selectivity of the subsequent dry development step. The resulting difference between the material properties of unexposed and exposed material can be tuned by adjusting one or more process conditions including temperature, gas flow, moisture, pressure, and/or RF power. The large process latitude enabled by dry development, which is not limited by material solubility in a wet developer solvent, allows more aggressive conditions to be applied during the treatment, further enhancing the material contrast that can be achieved. The resulting high material contrast feeds back a wider process window for dry development and thus enables increased productivity, lower cost, and better defectivity performance.

A substantial limitation of wet-developed resist films is limited temperature bakes. Wet development relies on differences in material solubility between exposed and unexposed regions of the photoresist. Heating the photoresist to elevated temperatures can greatly increase the degree of cross-linking in both exposed and unexposed regions of a metal-containing photoresist film. If the photoresist is heated to a temperature of about 220° C. or higher, both the exposed and unexposed regions of the photoresist become insoluble in the wet development solvents, so that the photoresist film can no longer by reliably developed using wet development techniques.

By contrast, for dry-developed resist films in which the dry etch rate difference (i.e., selectivity) between the exposed and unexposed regions of the photoresist is relied upon for removal of just the exposed or unexposed portion of the resist, the treatment temperature in a PAB or PEB can be varied across a much broader window, since the limitations that apply to solubility in a wet development solvent do not apply to dry etching techniques. As such, in the case of dry development, the treatment process may be tuned/optimized over a relatively wide temperature range. For example, the treatment temperature may range from about 90° C. to about 250° C., such as about 90° C. to about 190° C., for a PAB, and from about 150° C. to about 250° C. or more for a PEB. Decreased etch rate and greater etch selectivity have been found to occur with higher treatment temperatures in the noted ranges.

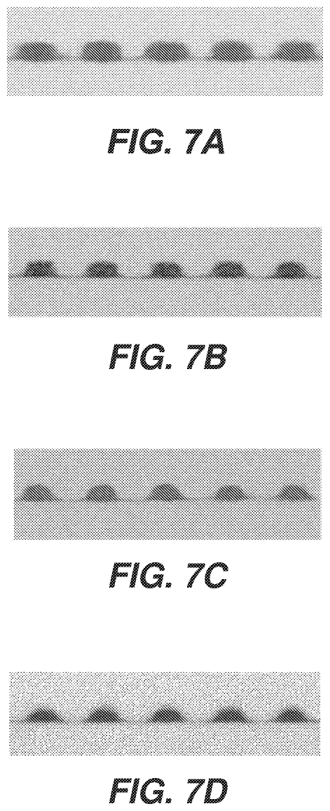

FIG. 7A-7D depict experimental results showing the improved material contrast and selectivity between unexposed and exposed portions of a photoresist layer that can be achieved by controlling temperature during a PEB. In each example, the substrate was exposed to a PEB in which the temperature of the substrate was controlled (e.g., by controlling the substrate support temperature). Afterwards, the photoresist layer on each substrate was developed using dry techniques to form a series of photoresist features on the substrate. In FIG. 7A, the temperature was controlled at about 235° C. In FIG. 7B, the temperature was controlled at about 220° C. In FIG. 7C, the temperature was controlled at about 205° C. In FIG. 7D, the temperature was controlled at about 190° C. At lower treatment temperatures, the photoresist profile showed significant tapering/rounded features. By contrast, at higher treatment temperatures, the photoresist profile is substantially improved, with the features being much less tapered/round, and much more square. The higher PEB temperatures provide greater material contrast between exposed and unexposed portions of the photoresist, thereby providing higher selectivity when the photoresist is developed. Further, the substrates treated with higher PEB temperatures show higher critical dimensions of the lines after development, which corresponds to a lower dose to size. In other words, the higher treatment temperatures can be used to achieve a desired critical dimension at a lower dose of EUV radiation than would be required to achieve the same critical dimension when the substrate is treated at lower temperatures (or not treated at all). As mentioned above, dry development techniques were used after the PEB treatments. In many cases, wet development techniques are not able to develop a photoresist layer that has been treated with a PEB at high temperatures, e.g., >180° C., for the reasons discussed above.

In particular embodiments, the PAB and/or PEB treatments may be conducted with gas ambient flow in the range of 100-10,000 sccm. In these or other embodiments, the moisture content in the ambient environment may be controlled between about a few percent up to 100% (e.g., in some cases between about 20%-50%). In these or other embodiments, a pressure during treatment may be controlled, for example at or below atmospheric pressure (e.g., using a vacuum to achieve sub-atmospheric pressures). In some cases, the pressure during treatment may be between about 0.1-760 Torr, for example between about 0.1-10 Torr, or between about 0.1-1 Torr in some cases. In these or other embodiments, a duration of the treatment may be controlled between about 1 to 15 minutes, for example between about 2 to 5 minutes, or about 2 minutes.

These findings can be used to tune the treatment conditions to tailor or optimize processing for particular materials and circumstances. For example, the selectivity achieved for a given EUV dose with a 220° C. to 250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity (e.g., a dry etch selectivity of up to 100:1 in exposed vs. unexposed regions of the photoresist) can be obtained than would be possible in a wet development context. Remote plasma-based treatments may result in the same or similar benefits.

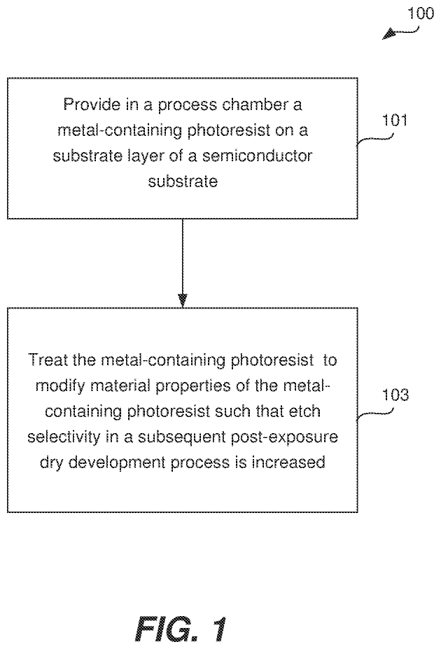

FIG. 1 depicts a process flow for one aspect of this disclosure, a method of processing a semiconductor substrate. The method 100 involves, at block 101, providing in a process chamber a metal-containing photoresist on a substrate layer of a semiconductor substrate. The substrate may be, for example, a partially fabricated semiconductor device film stack fabricated in any suitable way. At block 103, the metal-containing photoresist is treated to modify material properties of the metal-containing photoresist such that etch selectivity in a subsequent post-exposure dry development process is increased. For example, the treatment may result in increased cross-linking in the metal-containing photoresist.

In some embodiments, the treatment may involve a thermal process with control of temperature, gas ambient, and/or moisture. The gas ambient may include a reactive gas species such as air, water (H₂O), hydrogen (H₂), oxygen (O₂), ozone (O₃), hydrogen peroxide (H₂O₂), carbon monoxide (CO), carbon dioxide (CO₂), carbonyl sulfide (COS), sulfur dioxide (SO₂), chlorine (Cl₂), ammonia (NH₃), nitrous oxide (N₂O), nitric oxide (NO), methane (CH₄), methylamine (CH₃NH₂), dimethylamine ((CH₃)₂NH), trimethylamine (N(CH₃)₃), ethylamine (CH₃CH₂NH₂), diethylamine ((CH₃CH₂)₂NH), triethylamine (N(CH₂CH₃)₃), pyridine (C₅H₅N), alcohols (CₙH₂ₙ₊₁OH, including but not limited to methanol, ethanol, propanol, and butanol), acetyl acetone (CH₃COCH₂COCH₃), formic acid (HCOOH), oxalyl chloride ((COCl)₂), carboxylic acids (CₙH₂ₙ₊₁COOH), and other small molecule amines (NR¹R²R³, where each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof), etc. Substituted forms of any of these reactive gases may also be used. In some cases, the substrate may be exposed to two or more reactive gases during a treatment operation.

In embodiments where a reactive gas is used to treat the photoresist, the reactive gas may interact with the photoresist via oxidation, coordination, or acid/base chemistry.

In various embodiments, the gas ambient may include an inert gas such as nitrogen (N₂), argon (Ar), helium (He), neon (Ne), krypton (Kr), xenon (Xe), etc. In some cases, the inert gas may be provided together with one or more of the reactive gases listed above. In other cases, the gas ambient may be inert or substantially inert. For instance, the gas ambient may be free or substantially free of reactive gases. As used herein, a gas atmosphere may be considered substantially free of reactive gases if such gases are only present at trace amounts. In various cases where an inert atmosphere is used, the inert atmosphere may increase the contrast in composition and/or material properties by reducing over-oxidation in relevant areas of the photoresist. For instance, in some cases where the photoresist is treated thermally in an inert atmosphere after exposing the photoresist to patterning radiation, the inert atmosphere promotes an increase in material contrast (e.g., composition and/or material properties) by reducing over-oxidation present on unexposed areas of the photoresist.

Any of the embodiments described herein may include a reduction step, which may operate to reduce oxidized or over-oxidized areas of the photoresist. Such a reduction step may be particularly useful after a step that oxidizes the photoresist (or portions thereof). In various embodiments, the reduction step may involve exposing the substrate to a reducing atmosphere or an inert atmosphere. In some cases, the reduction step may involve heating the substrate and/or exposing the substrate to plasma. The plasma may be generated from inert gas and/or reducing gas.

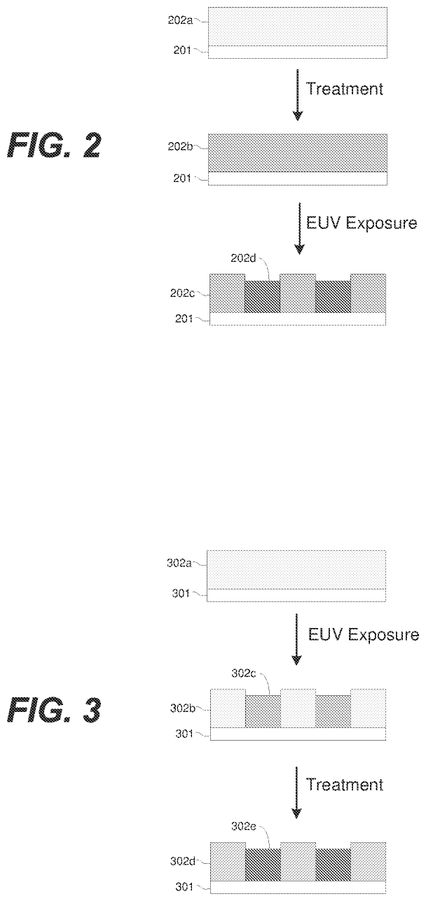

In various embodiments, as depicted in FIG. 2, the treatment may be applied after the photoresist 202a has been applied to the substrate 201, before the photoresist 202a is exposed to patterning radiation. For instance, in one example where the treatment is a thermal treatment, the treatment may be referred to as a post-application bake (PAB). The treatment alters the photoresist 202a to form a modified version of the photoresist 202b. As compared to the photoresist 202a prior to treatment, the modified version of the photoresist 202b exhibits improved properties. For instance, the modified version of the photoresist 202b may be more sensitive to EUV radiation than the unmodified version of the photoresist 202a. As a result of this increased EUV sensitivity, the modified version of the photoresist may exhibit lower dose to size during EUV exposure, and may provide lower line edge roughness after development.

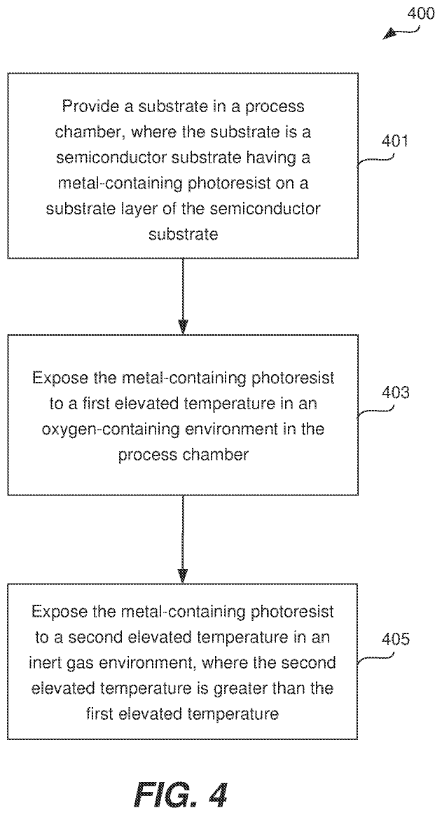

The treatment may also be provided at a different time. In various embodiments, as depicted in FIG. 3, the treatment may be applied after the photoresist 302a has been deposited and has been patterned by partial exposure to radiation (e.g., EUV), such that the substrate being treated includes both exposed portions 302c and unexposed portions 302b of the EUV photoresist. For instance, in one example where the treatment is a thermal treatment, the treatment may be referred to as a post-exposure bake (PEB). The treatment may modify both the exposed portions 302c and the unexposed portions 302b of the EUV photoresist, thereby forming a modified version of the exposed portion 302e and a modified version of the unexposed portion 302d. The modifications produced by the treatment may increase the etch rate of the photoresist material in a dry development etch gas. Alternatively or in addition, the modifications produced by the treatment may increase the difference in the composition/material properties between the unexposed portions and exposed portions of the photoresist. In other words, the difference between the composition/material properties when comparing (1) the modified version of the unexposed portion 302d of the photoresist after the treatment and (2) the modified version of the exposed portion 302e of the photoresist after the treatment, is more substantial than the difference between the composition/material properties when comparing (1) the unexposed portions 302b of the photoresist prior to treatment and (2) the exposed portions 302c of the photoresist prior to treatment.

Additionally, the ramping rate of the bake temperature in either PAB or PEB treatments is another useful process parameter that can be manipulated to fine-tune the cross-linking/etch selectivity results. The PAB and PEB thermal process can be done in either a single operation or in multiple operations. Where multiple operations are used, different process conditions may be provided during the individual operations. Example processing conditions that may vary between individual operations include, but are not limited to, the identity and concentration of ambient gases or mixtures proximate the substrate, moisture level, temperatures, pressures, etc. These processing conditions may be controlled to modulate the photoresist properties and therefore to tune different etch selectivity.

In an alternate embodiment, either or both of the post-application and post-exposure treatments may involve a remote plasma process, together with or instead of thermal processing, to generate radicals to react with the metal-containing photoresist to thereby modify its material properties. With reference to FIG. 2, in some embodiments the remote plasma treatment process occurs after the photoresist 202a is deposited and before it is exposed to EUV radiation. In this case, the treatment may be referred to as a post-application plasma treatment. With reference to FIG. 3, in some embodiments the remote plasma treatment process occurs after the photoresist 302a is deposited and exposed to EUV radiation to form exposed portions 302c and unexposed portions 302b. In this case, the treatment may be referred to as a post-exposure plasma treatment.

In implementations where a remote plasma is used to treat the photoresist, the radicals may be generated from the same or different gas species described herein with respect to the thermal treatment.

In some embodiments, multiple treatments may be used. For example, a first treatment may occur after photoresist deposition and prior to EUV exposure (as shown in FIG. 2), and a second treatment may occur after EUV exposure and prior to development (as shown in FIG. 3). One or more of the processing conditions may be controlled as described herein during the first treatment and/or during the second treatment.

### Multi-Step Post-Exposure Treatment of Metal-Containing Resist

PEB processes are often performed to further increase contrast in etch selectivity between exposed and unexposed portions of a metal-containing photoresist following exposure (e.g., EUV exposure). For instance, the metal-containing photoresist can be thermally treated in the presence of chemical species to facilitate cross-linking in EUV-exposed portions. For tin oxide photoresists, this is designed to drive evaporation of organic fragments generated during EUV exposure, oxidize any Sn—H, Sn—Sn, or Sn radical species generated by EUV exposure into metal hydroxide, and facilitate cross-linking between neighboring Sn—OH groups to form a more densely crosslinked SnO₂-like network. However, if the temperature is too high in the presence of an oxidizing atmosphere, then the EUV-unexposed portions of the metal-containing photoresist will over-oxidize. With over-oxidation, material contrast degrades, roughness increases, and defects increase in subsequent dry development processes. If the temperature is too low in the presence of an oxidizing atmosphere, then the EUV-exposed portions of the metal-containing photoresist will not sufficiently cross-link. As a result, material contrast is insufficient during exposure to dry development etch gas. If the PEB process is performed in an inert atmosphere at high temperatures, then the EUV-exposed portions of the metal-containing photoresist will fail to receive sufficient oxygen. Less oxygen in the EUV-exposed portions result in fewer cross-linkages, causing the EUV-exposed portions to be softer and less dense. Softer resist leads to additional roughness, which in turn leads to greater pattern deformation (e.g., line wiggling) and defects.

In the present disclosure, a photoresist on a substrate may undergo multiple PEB treatments or multiple steps in a PEB treatment process. The multiple bake steps may be performed at different temperatures and/or different chemistries. A first bake step may be performed at a moderately elevated bake temperature in an oxygen-rich environment. A second bake step may be performed at a highly elevated bake temperature greater than the moderately elevated bake temperature and in an inert environment. In some implementations, a moderately elevated bake temperature may be between about 150° C. and about 220° C. and the highly elevated bake temperature may be between about 220° C. and about 250° C. By exposing a metal-containing photoresist to the first bake step and the second bake step in sequence, material contrast is improved for achieving higher etch selectivity during dry development.

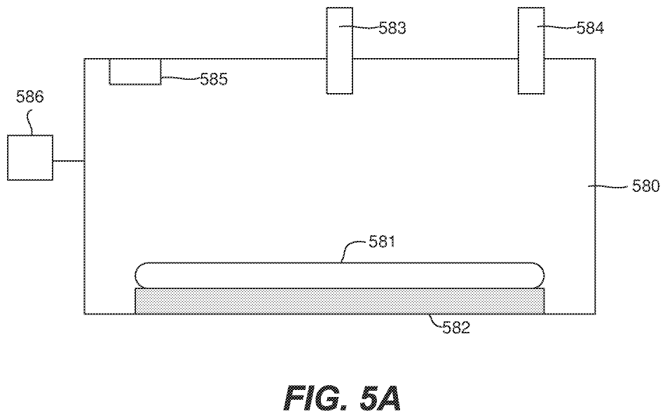

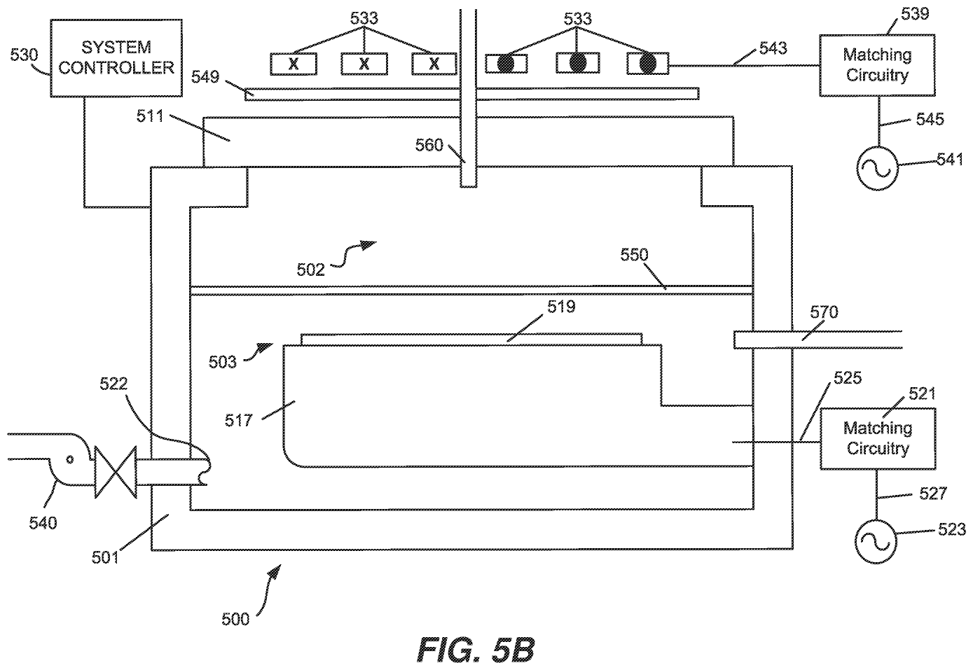

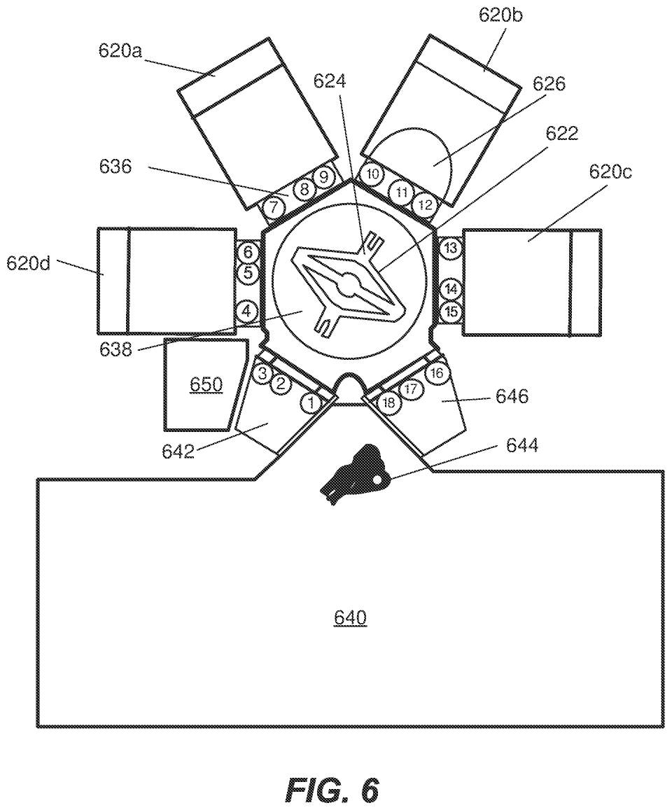

FIG. 4 provides a flow chart for a method of treating a substrate in a multi-step post-exposure bake treatment according to various embodiments. The operations of a process 400 may be performed in different order and/or with different, fewer, or additional operations. One or more operations of the process 400 may be performed using an apparatus described in any one of FIGS. 5A, 5B, and 6. In some embodiments, the operations of the process 400 may be implemented, at least in part, according to software stored in one or more non-transitory computer readable media.

At block 401 of the process 400, a substrate is provided in a process chamber, where the substrate is a semiconductor substrate having a metal-containing photoresist on a substrate layer of the semiconductor substrate. In some implementations, the substrate layer is a layer to be etched, where the substrate layer may include spin-on carbon (SoC), spin-on glass (SOG), amorphous carbon, silicon, silicon oxide, silicon nitride, silicon carbide, or silicon oxynitride. The metal-containing photoresist may be dry or wet deposited on the substrate layer. The metal-containing photoresist may be provided as a positive tone or negative tone resist having EUV-exposed and EUV-unexposed regions after EUV exposure. After exposure and an optional PEB treatment, the metal-containing photoresist may undergo development to selectively remove portions (e.g., EUV-unexposed portions) of the metal-containing photoresist to form a patterned mask over the substrate layer. In some implementations, the metal-containing photoresist is a metal-containing EUV photoresist, where the metal-containing EUV photoresist is an organo-metal oxide or organo-metal containing film. For instance, the metal-containing EUV photoresist may include Sn, O, and C atoms.

In some implementations, the process 400 further includes exposing the metal-containing EUV photoresist to EUV radiation prior to providing the substrate in the process chamber in order to form the EUV-exposed regions and the EUV-unexposed regions. After wet or dry depositing the metal-containing photoresist, the metal-containing photoresist can be photopatterned in a EUV lithography chamber (scanner) or module. The metal-containing photoresist may be an EUV-sensitive metal or metal oxide-containing film, e.g., organotin oxide. The EUV-sensitive metal or metal oxide-containing film may be photopatterned directly by EUV exposure in vacuum ambient.

After photopatterning metal-containing photoresist, the metal-containing photoresist is thermally treated or baked in a post-exposure bake (PEB) operation. This creates greater chemical contrast for development. Rather than performing a single bake operation, PEB treatment may proceed in a two-step or multi-step bake operation, where each step subjects the metal-containing photoresist to different treatment conditions. Such treatment conditions may include but are not limited to: identity and concentration of ambient gases or mixtures proximate the substrate, moisture level, temperatures, pressures, etc. One of the steps may expose the substrate to at least a different temperature and different ambient gas. For example, one of the bake steps may expose the substrate to a low or moderately elevated temperature in an oxidizing atmosphere and another one of the bake steps may expose the substrate to a highly elevated temperature in a non-oxidizing atmosphere. These steps may be performed in sequence as illustrated at blocks 403 and 405 below.

At block 403 of the process 400, the metal-containing photoresist is exposed to a first elevated temperature in an oxygen-containing environment in the process chamber. The first elevated temperature provides a low to medium temperature bake. The low to medium temperature bake may prevent over-oxidation of unexposed portions of the metal-containing photoresist. In some implementations, the first elevated temperature is between about 150° C. and about 220° C., or between about 180° C. and about 220° C. The oxygen-containing environment may facilitate incorporation of oxygen into exposed portions of the metal-containing photoresist. Higher oxygen concentration generally leads to higher oxygen incorporation. In some implementations, the oxygen-containing environment includes an oxygen-containing species or oxidant. Oxygen partial pressure in the oxygen-containing environment may be at least about 100 Torr such as between about 100 Torr and about 600 Torr. Depending on the oxygen partial pressure, the oxidant may occupy a certain concentration of the total gas concentration. In some embodiments, a concentration of the oxidant may be at least 20 volume % in the oxygen-containing environment. For example, the concentration of the oxidant may be between about 25 volume % and about 100 volume %, or between about 50 volume % and about 100 volume %. In some implementations, the oxygen-containing environment includes oxygen (O₂), ozone (O₃), water (H₂O), hydrogen peroxide (H₂O₂), carbon monoxide (CO), carbon dioxide (CO₂), or combinations thereof.

A higher bake temperature generally leads to increased material contrast between exposed and unexposed portions of the metal-containing photoresist. However, if the bake temperature is too high, over-oxidation of unexposed portions of the metal-containing photoresist occurs. Without being limited by any theory for organo-metal containing film, metal-carbon bond cleavage can occur in excessively high bake temperatures, leaving behind metal hydride sites that can be converted to metal hydroxides in the presence of an oxygen-containing environment. The metal hydroxides may crosslink to form metal oxide moieties. Consequently, unexposed and exposed portions of the metal-containing photoresist are less differentiated in terms of chemical structure, which results in reduced etch contrast during a subsequent dry development process. Reduced etch contrast can be attributable to increased line CD variation, photoresist corner rounding, and higher dose to size. In addition, reduced etch contrast due to over-oxidation can be attributable to poor pattern development, increased likelihood of forming residues in unexposed portions, increased line edge roughness, and line bridging in patterned photoresist to further increase defectivity. Thus, it is desirable to limit the bake temperature in the oxygen-containing environment to a low or medium bake temperature (e.g., less than about 220° C.) that prevents over-oxidation of the unexposed portions of the metal-containing photoresist.

The presence of oxygen-containing species (e.g., O₂, O₃, etc.) generally leads to increased material contrast between exposed and unexposed portions of the metal-containing photoresist. An oxygen-rich bake increases the partial pressure of the oxygen-containing species, which lowers the temperature required to incorporate the same amount oxygen into the exposed portions of the metal-containing photoresist. By operating at a lower temperature, this prevents over-oxidation of the unexposed portions of the metal-containing photoresist. Oxygen-containing species will promote crosslinking in exposed portions of the metal-containing photoresist. Without being limited by any theory, oxygen will attach to metal hydride sites to form metal hydroxides. Metal hydroxides (e.g., Sn—OH) form crosslinks to produce metal oxide moieties (e.g., Sn—O—Sn) and water (H₂O). A more densely crosslinked metal oxide network provides greater etch contrast between exposed and unexposed portions of the metal-containing photoresist. Increased etch contrast provides increased etch selectivity, which leads to reduced line CD variation, a more square photoresist profile, and lower dose to size. Furthermore, increased etch contrast leads to improved pattern development, reduced likelihood of forming residues in unexposed portions, reduced line edge roughness, and reduced defectivity.

A duration of exposure to the first elevated temperature in the oxygen-containing environment may be tuned to optimize PEB treatment. In some implementations, the duration of exposure may be between about 30 seconds and about 10 minutes or between about 1 minute and about 5 minutes. Longer exposure times may allow for more oxygen incorporation in the exposed portions of the metal-containing photoresist, which can improve material contrast. On the flip side, exposure times that are too long can lead to over-oxidation in the unexposed portions of the metal-containing photoresist.

A pressure in the process chamber can be controlled during exposure to the oxygen-containing environment to optimize PEB treatment. Specifically, a partial pressure of the oxygen-containing species can be tuned to achieve a desired amount of oxygen incorporation in the exposed portions of the metal-containing photoresist. For instance, the partial pressure of the oxygen-containing species may be between about 10 Torr and about 760 Torr, at least about 100 Torr, or between about 100 Torr and about 600 Torr. Oxygen-containing species may be flowed in the process chamber with a balance of inert gas. In some implementations, a concentration of the oxygen-containing species may be at least 20 volume % and as high as 100 volume %. In some cases, the partial pressure of the oxygen-containing species may control PEB treatment performance regardless of the total chamber pressure. By way of an example, a chamber pressure of 600 Torr with a concentration of oxygen at 20 volume % can lead to the same result in PEB treatment performance as a chamber pressure of 120 Torr with a concentration of oxygen at 100 volume %.

Moisture level in the process chamber can be tuned during exposure to the oxygen-containing environment to optimize PEB treatment. In some cases, increased moisture leads to line CD decrease or other adverse outcomes. Without being limited by any theory, increased humidity levels suppress crosslinking in exposed portions of the metal-containing photoresist, thereby lowering material contrast. Accordingly, the moisture level in the process chamber is minimized. In some implementations, the process chamber is free or substantially free of moisture.

Queue time between the exposing the metal-containing photoresist for photopatterning and exposing the metal-containing photoresist to the oxygen-containing environment can be minimized to optimize PEB treatment. Longer queue times lead to higher dose to size and increased roughness. Therefore, it is desirable for the queue time between EUV exposure and PEB treatment in the oxygen-containing environment to be as short as possible. For instance, the queue time between EUV exposure and PEB treatment in the oxygen-containing environment is less than about 3 hours, less than about 2 hours, less than about 1 hour, less than about 20 minutes, or less than about 10 minutes.

In some implementations, the low to medium temperature bake (i.e., first elevated temperature) can be replaced or supplemented with remote plasma. The remote plasma may be employed to increase oxygen radicals to increase productivity. Oxygen radicals provide reactive species for incorporation in the exposed portions of the metal-containing photoresist. The oxygen radicals may be generated in a remote plasma source and supplied towards the substrate in the process chamber.

The process chamber may include one or more heaters for temperature control. In some implementations, the one or more heaters may be coupled to a heating assembly that faces the substrate in the process chamber for substrate temperature control. For example, the heating assembly may be positioned underneath a substrate support or between the substrate support and the substrate. In some embodiments, the substrate temperature may be controlled using a radiant heating assembly such as an IR lamp or one or more LEDs.

At block 405 of the process 400, the metal-containing photoresist is exposed to a second elevated temperature in an inert gas environment, where the second elevated temperature is greater than the first elevated temperature. Exposure to the inert gas environment may occur in the same process chamber or a different process chamber than exposure to the oxygen-containing environment. The second elevated temperature provides a high temperature bake. The high temperature bake provides sufficient thermal energy to promote crosslinking in the exposed portions of the metal-containing photoresist. In some implementations, the second elevated temperature is between about 220° C. and about 300° C., or between about 220° C. and about 250° C. The inert gas environment is free or substantially free of oxygen-containing species to avoid over-oxidation of unexposed portions of the metal-containing photoresist. In some implementations, the inert gas environment includes nitrogen (N₂), helium (He), neon (Ne), argon (Ar), krypton (Kr), xenon (Xe), or combinations thereof.

Exposure to the inert gas environment at the second elevated temperature (also referred to as “a second bake”) occurs in sequence following exposure to the oxygen-containing environment at the first elevated temperature (also referred to as “a first bake”). The first bake provides oxygen incorporation into exposed portions while preventing over-oxidation in unexposed portions of the metal-containing photoresist. The second bake performed in the inert gas environment facilitates reactions between incorporated oxygen and metal centers in the exposed portions of the metal-containing photoresist, thereby promoting cross-linking to form more densely crosslinked metal oxide networks. Moreover, the inert gas environment prevents over-oxidation in the unexposed portions of the metal-containing photoresist. The second bake provides greater differentiation between unexposed and exposed portions of the metal-containing photoresist for increased etch contrast during a subsequent dry development process. The increased etch contrast and dry development selectivity feeds back a wider process window for dry development that can improve productivity, lower cost, lower dose to size, and better defectivity performance.

In some implementations, the process 400 further includes repeating the first bake and the second bake multiple times. Multiple cycles of the first bake and the second bake may further increase etch contrast.

A duration of exposure to the second elevated temperature in the inert gas environment may be tuned to optimize PEB treatment. In some implementations, the duration of exposure may be between about 30 seconds and about 10 minutes or between about 1 minute and about 5 minutes. Longer exposure times enable more crosslinking in the exposed portions of the metal-containing photoresist to improve material contrast. However, exposure times that are too long can eventually form crosslinked metal oxide networks in the unexposed portions of the metal-containing photoresist.

The inert gas environment can be controlled to minimize an amount of reactive species. The concentration of reactive species including oxygen-containing species in the inert gas environment may be limited to avoid over-oxidation. Oxygen partial pressure may be equal to or less than about 20 Torr, equal to or less than about 10 Torr, or equal to or less than about 5 Torr. In some implementations, the concentration of oxygen-containing species is equal to or less than about 10 volume %, equal to or less than about 5 volume %, equal to or less than about 1 volume %, or equal to or less than about 0.5 volume %. The reactive species may be present in trace amounts relative to inert gas species in the inert gas environment.

Moisture level in the process chamber can be tuned during exposure to the inert gas environment to optimize PEB treatment. As discussed above, increased humidity can lead to reduced etch contrast. Therefore, a process chamber for performing the second bake may be free or substantially free of moisture.

Queue time between the exposing the metal-containing photoresist to the oxygen-containing environment and exposing the metal-containing photoresist to the inert gas environment can be minimized to optimize PEB treatment. Longer queue times lead to increased line CD and increased roughness. Dose to size is not as sensitive to longer queue times. Nonetheless, it is generally desirable for the queue time between the first bake and the second bake to be short. For instance, the queue time between the first bake and the second bake is less than about 3 hours, less than about 2 hours, less than about 1 hour, less than about 20 minutes, or less than about 10 minutes.

Overall, performing the sequence of the first bake followed by the second bake improves PEB treatment performance compared to a single bake operation. Performing the first bake and the second bake improves etch contrast for improved etch selectivity between EUV-exposed portions and EUV-unexposed portions in a subsequent dry development process. Further, performing the first bake and the second bake can reduce line edge roughness and reduce dose to size in the subsequent dry development process.

### Apparatus

FIGS. 5A and 5B depict schematic illustrations of different embodiments of process stations that may be used to perform the treatments described herein. The process station 580 shown in FIG. 5A may be used for thermal-based treatments such as a post-application bake or a post-exposure bake. The process station 500 shown in FIG. 5B may be used for thermal-based treatments, remote plasma treatments, or both. These treatments can include post-application treatments as well as post-exposure treatments. These treatments can further include multi-step post-exposure treatments as described above. The process stations shown in FIGS. 5A and 5B may also be used for other processes described herein. For steps where plasma is required, the process station 500 of FIG. 5B may be used. For steps where plasma is not required, either the process station 500 of FIG. 5B or the process station 580 of FIG. 5A may be used.

FIG. 5A presents a simplified view of a processing chamber 580 according to one embodiment. In this example, the processing chamber 580 is a closed chamber having a controllable atmosphere. The substrate 581 may be positioned on substrate support 582, which may also heat and/or cool the substrate. Alternative or additional heating and cooling elements may be provided in some cases. Processing gases enter the processing chamber 580 through inlet 583. Materials are removed from the processing chamber 580 through outlet 584, which may be connected to a vacuum source (not shown). Operation of the processing chamber 580 may be controlled by a controller 586, which is further discussed below. Further, a sensor 585 may be provided, for example to monitor the temperature and/or the composition of the atmosphere in the processing chamber 580. Readings from sensor 585 may be used by controller 586 in an active feedback loop. In various implementations, processing chamber 580 may be modified by including a remote plasma chamber (not shown) in fluidic communication with processing chamber 580. In such cases, plasma may be generated in the remote plasma chamber before the plasma is delivered to the processing chamber 580.

The chamber in which the treatment takes place may be configured in a number of ways. In some embodiments, the chamber is the same chamber used to deposit the photoresist, and/or the same chamber used to expose the photoresist to EUV radiation, and/or the same chamber used to develop the photoresist. In some embodiments, the chamber is a dedicated bake or remote plasma treatment chamber that is not used for other processes such as deposition, etching, EUV exposure, or photoresist development. The chamber may be a standalone chamber, or it may be integrated into a larger processing tool such as the deposition tool used to deposit the photoresist, the EUV exposure tool used to expose the photoresist to EUV radiation, and/or the development tool used to develop the photoresist. The chamber used for treating the photoresist may be combined with any one or more of these tools, for example in a cluster tool, as desired for a particular application. In some cases, the chamber may be provided in a common low pressure process tool environment that provides a low pressure for multiple chambers.

FIG. 5B schematically shows a cross-sectional view of an inductively coupled plasma apparatus 500 appropriate for implementing certain embodiments or aspects of embodiments such as vapor (dry) deposition, thermal treatment as described herein, plasma treatment as described herein, dry development and/or etch, an example of which is a Kiyo® reactor, produced by Lam Research Corporation of Fremont, CA. In other embodiments, other tools or tool types having the functionality to conduct one or more operations of the dry deposition, treatment (thermal or remote plasma), development and/or etch processes described herein may be used for implementation.

The inductively coupled plasma apparatus 500 includes an overall process chamber 524 structurally defined by chamber walls 501 and a window 511. The chamber walls 501 may be fabricated from stainless steel or aluminum. The window 511 may be fabricated from quartz or other dielectric material. An optional internal plasma grid 550 divides the overall process chamber into an upper sub-chamber 502 and a lower sub chamber 503. In certain embodiments, plasma grid 550 may be removed, thereby utilizing a chamber space made of sub chambers 502 and 503. In places where plasma grid 550 is present, it may be used to shield the substrate from the plasma directly generated in the upper sub-chamber 502, such that the substrate is processed with a remote plasma in the lower sub-chamber 503. In this example, the plasma present in the lower sub-chamber 503 may be considered a remote plasma because it is first generated at a location (e.g., the upper sub-chamber 502) that is upstream from where the substrate is treated with the plasma (e.g., the lower sub-chamber 503).

A chuck 517 is positioned within the lower sub-chamber 503 near the bottom inner surface. The chuck 517 is configured to receive and hold a semiconductor wafer 519 upon which the etching and deposition processes are performed. The chuck 517 can be an electrostatic chuck for supporting the wafer 519 when present. In some embodiments, an edge ring (not shown) surrounds chuck 517 and has an upper surface that is approximately planar with a top surface of the wafer 519, when present over chuck 517. The chuck 517 also includes electrostatic electrodes for chucking and dechucking the wafer 519. A filter and DC clamp power supply (not shown) may be provided for this purpose. Other control systems for lifting the wafer 519 off the chuck 517 can also be provided. The chuck 517 can be electrically charged using an RF power supply 523. The RF power supply 523 is connected to matching circuitry 521 through a connection 527. The matching circuitry 521 is connected to the chuck 517 through a connection 525. In this manner, the RF power supply 523 is connected to the chuck 517. In various embodiments, a bias power of the electrostatic chuck may be set at about a 50V or may be set at a different bias power depending on the process performed in accordance with disclosed embodiments. For example, the bias power may be between about 20 Vb and about 100 V, or between about 30 V and about 150 V.

Elements for plasma generation include a coil 533 positioned above window 511. In some embodiments, a coil is not used. In some such embodiments, an alternative mechanism for generating a plasma may be provided, for instance for providing a capacitively coupled plasma, a microwave plasma, etc. In cases where an inductively coupled plasma is used, the coil 533 is fabricated from an electrically conductive material and includes at least one complete turn. The example of a coil 533 shown in FIG. 5B includes three turns. The cross sections of coil 533 are shown with symbols, and coils having an “X” extend rotationally into the page, while coils having a “o” extend rotationally out of the page. Elements for plasma generation also include an RF power supply 541 configured to supply RF power to the coil 533. In general, the RF power supply 541 is connected to matching circuitry 539 through a connection 545. The matching circuitry 539 is connected to the coil 533 through a connection 543. In this manner, the RF power supply 541 is connected to the coil 533.

An optional Faraday shield 549a is positioned between the coil 533 and the window 511. The Faraday shield 549a may be maintained in a spaced apart relationship relative to the coil 533. In some embodiments, the Faraday shield 549a is disposed immediately above the window 511. In some embodiments, the Faraday shield 549b is between the window 511 and the chuck 517. In some embodiments, the Faraday shield 549b is not maintained in a spaced apart relationship relative to the coil 533. For example, the Faraday shield 549b may be directly below the window 511 without a gap. The coil 533, the Faraday shield 549a, and the window 511 are each configured to be substantially parallel to one another. The Faraday shield 549a may prevent metal or other species from depositing on the window 511 of the process chamber 524.

Process gases may be flowed into the process chamber through one or more main gas flow inlets 560 positioned in the upper sub-chamber 502 and/or through one or more side gas flow inlets 570. Likewise, though not explicitly shown, similar gas flow inlets may be used to supply process gases to a capacitively coupled plasma processing chamber. A vacuum pump, e.g., a one or two stage mechanical dry pump and/or turbomolecular pump 540, may be used to draw process gases out of the process chamber 524 and to maintain a pressure within the process chamber 524. For example, the vacuum pump may be used to evacuate the overall process chamber 524 or the lower sub-chamber 503 during a purge operation. A valve-controlled conduit may be used to fluidically connect the vacuum pump to the process chamber 524 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 500, one or more process gases may be supplied through the gas flow inlets 560 and/or 570. In certain embodiments, process gas may be supplied only through the main gas flow inlet 560, or only through the side gas flow inlet 570. In some cases, the gas flow inlets shown in the figure may be replaced by more complex gas flow inlets, one or more showerheads, for example. The Faraday shield 549a and/or optional grid 550 may include internal channels and holes that allow delivery of process gases to the process chamber 524. Either or both of Faraday shield 549a and optional grid 550 may serve as a showerhead for delivery of process gases. In some embodiments, a liquid vaporization and delivery system may be situated upstream of the process chamber 524, such that once a liquid reactant or precursor is vaporized, the vaporized reactant or precursor is introduced into the process chamber 524 via a gas flow inlet 560 and/or 570.

In some embodiments, a remote plasma generation unit may be provided upstream of the process chamber 524, and radicals formed by the remote plasma may be provided to the process chamber via a gas flow inlet 560 and/or 570.

Radio frequency power is supplied from the RF power supply 541 to the coil 533 to cause an RF current to flow through the coil 533. The RF current flowing through the coil 533 generates an electromagnetic field about the coil 533. The electromagnetic field generates an inductive current within the upper sub-chamber 502. The physical and chemical interactions of various generated ions and radicals with the wafer 519 etch features of and selectively deposit layers on the wafer 519.

If the plasma grid 550 is used such that there is both an upper sub-chamber 502 and a lower sub-chamber 503, the inductive current acts on the gas present in the upper sub-chamber 502 to generate an electron-ion plasma in the upper sub-chamber 502. The optional internal plasma grid 550 limits the amount of hot electrons in the lower sub-chamber 503. In some embodiments, the apparatus 500 is designed and operated such that the plasma present in the lower sub-chamber 503 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 503 through port 522. The chuck 517 disclosed herein may operate at elevated temperatures ranging between about 10° C. and about 250° C. or more. The temperature will depend on the process operation and specific recipe.

Apparatus 500 may be coupled to facilities (not shown) when installed in a clean room or a fabrication facility. Facilities include plumbing that provide processing gases, vacuum, temperature control, and environmental particle control. These facilities are coupled to apparatus 500, when installed in the target fabrication facility. Additionally, apparatus 500 may be coupled to a transfer chamber that allows robotics to transfer semiconductor wafers into and out of apparatus 500 using typical automation.

In some embodiments, a system controller 530 (which may include one or more physical or logical controllers) controls some or all of the operations of a process chamber 524. The system controller 530 may include one or more memory devices and one or more processors. In some embodiments, the apparatus 500 includes a switching system for controlling flow rates and durations when disclosed embodiments are performed. In some embodiments, the apparatus 500 may have a switching time of up to about 500 ms, or up to about 750 ms. Switching time may depend on the flow chemistry, recipe chosen, reactor architecture, and other factors.

In some implementations, the system controller 530 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 530, which may control various components or subparts of the system or systems. The system controller 530, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 530 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 530, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 530 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 530 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (e.g., PECVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 6 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 6 depicts a semiconductor process cluster tool architecture with vacuum-integrated deposition and patterning modules suitable for implementation of the embodiments described herein. Such a cluster process tool architecture can include PR and underlayer deposition modules, resist exposure (EUV scanner) modules, and/or resist dry development and etch modules, as described herein. In some embodiments, one or more hardware parameters of the process station including those discussed in detail herein may be adjusted programmatically by one or more computer controllers.

In some embodiments, certain of the processing functions can be performed consecutively in the same module, for example resist film vapor deposition, treatment, exposure and/or dry development and etch. And embodiments of this disclosure are directed to apparatus for processing a substrate such as an apparatus for treating metal-containing photoresist. The apparatus has a process chamber comprising a substrate support configured to support a semiconductor substrate having a substrate layer and a metal-containing photoresist positioned over the substrate layer. The apparatus can further include a process gas source connected with the process chamber and associated flow-control hardware, thermal control hardware, substrate handling hardware connected with the process chamber, and a controller having a processor and a memory. In some implementations, the processor and the memory are communicatively connected with one another, the processor is at least operatively connected with the flow-control and substrate handling hardware, and the memory stores computer-executable instructions for conducting the operations in the methods of making a pattering structure described herein.

In some implementations, the controller having the processor and memory may be configured with computer-executable instructions for performing the following operations: expose a metal-containing EUV photoresist to a first elevated temperature in an oxygen-containing environment in the process chamber, and expose the metal-containing EUV photoresist to a second elevated temperature in an inert gas environment, where the second elevated temperature is greater than the first elevated temperature. In some implementations, the first elevated temperature is between about 150° C. and about 220° C. and the second elevated temperature is between about 220° C. and about 250° C.

As noted above, FIG. 6 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster. The treatment steps described herein may be performed in any one or more of these modules, or in a separate module dedicated to such treatments.

A vacuum transport module (VTM) 638 interfaces with four processing modules 620a-620d, which may be individually optimized to perform various fabrication processes. By way of example, processing modules 620a-620d may be implemented to perform deposition, evaporation, thermal and/or plasma treatment, electroless deposition, dry development, etch, strip, and/or other semiconductor processes. For example, module 620a may be an ALD reactor that may be operated to perform non-plasma, thermal atomic layer depositions to form metal-containing photoresist or other materials described herein. In one example, module 620a is a Vector® tool, available from Lam Research Corporation of Fremont, CA. In these or other embodiments, module 620b may be a plasma enhanced chemical vapor deposition (PECVD) tool, such as the Lam Vector®. It should be understood that the figure is not necessarily drawn to scale.

Airlocks 642 and 646, also known as a loadlocks or transfer modules, interface with the VTM 638 and a patterning module 640. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUV lithography also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUV lithography scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 6 but without the integrated patterning module.

Airlock 642 may be an “outgoing” loadlock, referring to the transfer of a substrate out from the VTM 638 serving a deposition module 620a to the patterning module 640, and airlock 646 may be an “ingoing” loadlock, referring to the transfer of a substrate from the patterning module 640 back in to the VTM 638. The ingoing loadlock 646 may also provide an interface to the exterior of the tool for access and egress of substrates. Each process module has a facet that interfaces the module to VTM 638. For example, deposition process module 620a has facet 636. Inside each facet, sensors, for example, sensors 1-18 as shown, are used to detect the passing of wafer 626 when moved between respective stations. Patterning module 640 and airlocks 642 and 646 may be similarly equipped with additional facets and sensors, not shown.

Main VTM robot 622 transfers wafer 626 between modules, including airlocks 642 and 646. In one embodiment, robot 622 has one arm, and in another embodiment, robot 622 has two arms, where each arm has an end effector 624 to pick wafers such as wafer 626 for transport. Front-end robot 644, in is used to transfer wafers 626 from outgoing airlock 642 into the patterning module 640, from the patterning module 640 into ingoing airlock 646. Front-end robot 644 may also transport wafers 626 between the ingoing loadlock and the exterior of the tool for access and egress of substrates. Because ingoing airlock module 646 has the ability to match the environment between atmospheric and vacuum, the wafer 626 is able to move between the two pressure environments without being damaged.

It should be noted that a EUV lithography tool typically operates at a higher vacuum (e.g., lower pressure) than a deposition tool. If this is the case, it is desirable to increase the vacuum environment of the substrate (e.g., apply greater vacuum such that the substrate is exposed to lower pressure) during the transfer between the deposition tool and the EUV lithography tool to allow the substrate to degas prior to entry into the EUV lithography tool. Outgoing airlock 642 may provide this function by holding the transferred wafers at a lower pressure, no higher than the pressure in the patterning module 640, for a period of time and exhausting any off-gassing, so that the optics of the patterning tool 640 are not contaminated by off-gassing from the substrate. A suitable pressure for the outgoing, off-gassing airlock is no more than about 1E-8 Torr.

In some embodiments, a system controller 650 (which may include one or more physical or logical controllers) controls some or all of the operations of the cluster tool and/or its separate modules. An example system controller is discussed further above in relation to FIG. 4B. It should be noted that the controller can be local to the cluster architecture, or can be located external to the cluster architecture in the manufacturing floor, or in a remote location and connected to the cluster architecture via a network. The system controller 650 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include one or more processing chambers for patterning, deposition and/or etch, and a controller including instructions for forming a negative pattern mask. One or more of the processing chambers may be configured to perform one or more of the treatment steps described herein. The instructions may include code for, in a relevant processing chamber or chambers, patterning a feature in a metal-oxide resist on a semiconductor substrate by dry deposition, treatment as described herein, EUV exposure to expose a surface of the substrate, dry developing the photopatterned resist, and/or etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network. A controller as described above with respect to FIG. 5B may be implemented with the tool in FIG. 6.

### CONCLUSION

Treatment strategies (e.g., post-application bake, post-exposure bake, post-application remote plasma treatment, and post-exposure remote plasma treatment) to enhance EUV-lithographic dry development performance of metal-containing EUV resist are disclosed.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

The following claims are provided for further illustration of certain embodiments of the disclosure. The disclosure is not necessarily limited to these embodiments.

What is claimed is:

1. A method of treating metal-containing extreme ultraviolet (EUV) photoresist, the method comprising:
providing a substrate in a process chamber, wherein the substrate is a semiconductor substrate comprising a substrate layer and a metal-containing EUV photoresist positioned over the substrate layer;
exposing the metal-containing EUV photoresist to a first elevated temperature in an oxygen-containing environment in the process chamber; and
exposing the metal-containing EUV photoresist to a second elevated temperature in an inert gas environment, wherein the second elevated temperature is greater than the first elevated temperature.

2. The method of claim 1, wherein the metal-containing EUV photoresist includes EUV-exposed portions and EUV-unexposed portions, wherein exposure to the first elevated temperature in the oxygen-containing environment and exposure to the second elevated temperature in the inert gas environment increase etch selectivity between the EUV-exposed portions and the EUV-unexposed portions in a subsequent dry development process.

3. The method of claim 2, wherein exposure to the first elevated temperature in the oxygen-containing environment and exposure to the second elevated temperature in the inert gas environment reduce line edge roughness (LER) and reduce dose to size (DtS) in the subsequent dry development process.

4. The method of claim 2, further comprising:
exposing the metal-containing EUV photoresist to EUV radiation prior to providing the substrate in the process chamber in order to form the EUV-exposed regions and the EUV-unexposed regions.

5. The method of claim 4, wherein a first queue time between exposure to EUV radiation and exposure to the first elevated temperature is less than about 20 minutes, and wherein a second queue time between exposure to the first elevated temperature and exposure to the second elevated temperature is less than about 1 hour.

6. The method of claim 1, wherein the first elevated temperature is between about 150° C. and about 220° C. and the second elevated temperature is between about 220° C. and about 250° C.

7. The method of claim 1, wherein the oxygen-containing environment includes an oxygen-containing species, wherein a partial pressure of the oxygen-containing species is at least about 100 Torr in the oxygen-containing environment.

8. The method of claim 1, wherein the oxygen-containing environment includes oxygen (O₂), ozone (O₃), water (H₂O), hydrogen peroxide (H₂O₂), carbon monoxide (CO), carbon dioxide (CO₂), or combinations thereof.

9. The method of claim 1, wherein the inert gas environment includes nitrogen (N₂), helium (He), neon (Ne), argon (Ar), xenon (Xe), or combinations thereof.

10. The method of claim 1, wherein each of the oxygen-containing environment and the inert gas environment is free or substantially free of moisture.

11. The method of claim 1, wherein the metal-containing EUV photoresist is a metal oxide-containing EUV photoresist.

12. The method of claim 1, wherein the oxygen-containing environment comprises oxygen radicals and ions generated from a remote plasma source for exposing the metal-containing EUV photoresist to the oxygen radicals and ions.

13. The method of claim 1, wherein exposing the metal-containing EUV photoresist to the second elevated temperature in the inert gas environment occurs in the same process chamber as exposing the metal-containing EUV resist to the first elevated temperature in the oxygen-containing environment.

14. The method of claim 1, further comprising:
repeating steps of exposing the metal-containing EUV photoresist to the oxygen-containing environment and exposing the metal-containing EUV photoresist to the inert gas environment for one or more times.

15. The method of claim 1, further comprising:
dry developing the metal-containing EUV photoresist to selectively remove portions of the metal-containing EUV photoresist, wherein exposure to the first elevated temperature in the oxygen-containing environment and exposure to the second elevated temperature in the inert gas environment are post-exposure bake (PEB) operations performed prior to dry development.

16. An apparatus for treating metal-containing EUV photoresist, the apparatus comprising:
a process chamber comprising a substrate support, wherein the substrate support is configured to support a semiconductor substrate comprising a substrate layer and a metal-containing EUV photoresist positioned over the substrate layer;
a process gas source connected with the process chamber and associated gas-flow control hardware;
a substrate thermal control hardware; and
a controller configured with instructions for performing the following operations:
expose the metal-containing EUV photoresist to a first elevated temperature in an oxygen-containing environment in the process chamber; and
expose the metal-containing EUV photoresist to a second elevated temperature in an inert gas environment, wherein the second elevated temperature is greater than the first elevated temperature.

17. The apparatus of claim 16, wherein the first elevated temperature is between about 150° C. and about 220° C. and the second elevated temperature is between about 220° C. and about 250° C.

18. The apparatus of claim 16, wherein each of the oxygen-containing environment and the inert gas environment is free or substantially free of moisture.

19. The apparatus of claim 16, wherein a partial pressure of an oxygen-containing species is at least about 100 Torr in the oxygen-containing environment.

20. The apparatus of claim 16, wherein the oxygen-containing environment includes an oxygen-containing species, wherein a concentration of the oxygen-containing species is at least 20 volume % in the oxygen-containing environment, wherein the oxygen-containing species oxygen (O₂), ozone (O₃), water (H₂O), hydrogen peroxide (H₂O₂), carbon monoxide (CO), carbon dioxide (CO₂), or combinations thereof.
